(19) United States
(12) Patent Application Publication
(10) Pub. No.: US 2013/0100368 A1
(43) Pub. Date: Apr. 25, 2013

(54) LIQUID CRYSTAL DISPLAY DEVICE AND MANUFACTURING METHOD THEREFOR

(71) Applicant: Japan Display East Inc., Mobara-shi (JP)

(72) Inventors: Hiroyuki YARITA, Mobara (JP); Kimitoshi OUGIICHI, Mobara (JP); Hideki KURIYAMA, Mobara (JP)

(73) Assignee: JAPAN DISPLAY EAST INC., Mobara-shi (JP)

(21) Appl. No.: 13/659,942

(22) Filed: Oct. 25, 2012

(30) Foreign Application Priority Data
Oct. 25, 2011 (JP) 2011-233834

(51) Int. Cl. G02F 1/136; H01L 33/42

(52) U.S. Cl. 349/42; 438/30; 257/E33.064

(57) ABSTRACT

A liquid crystal display device includes a first insulating layer which sits on an end portion of a first transparent electrode, a gate electrode under the first insulating layer, a semiconductor layer on the first insulating layer, a first wiring which is formed so as to reach the first transparent electrode thereon from the semiconductor layer and is electrically connected to the first transparent electrode, a second wiring which is pulled out from the upper part of the semiconductor layer with an interval from the first wiring, a second insulating layer which covers the first wiring, the second wiring, the semiconductor layer, and the second insulating layer which covers the first transparent electrode, a second transparent electrode which is formed on the second insulating layer, and a liquid crystal layer which is arranged on the second transparent electrode.

### CROSS-REFERENCE TO RELATED APPLICATION

The present application claims priority from Japanese application JP 2011-233834 filed on Oct. 25, 2011, the contents of which are hereby incorporated by reference into this application.

### BACKGROUND OF THE INVENTION

1. Field of the Invention

The present invention relates to a liquid crystal display device, and a manufacturing method therefor.

### BACKGROUND ART

2. Description of the Related Art

In a lateral electric field liquid crystal display panel, a pair of electrodes is provided by being insulated from each other on one inner surface side of a pair of substrates which is arranged by interposing a liquid crystal layer therebetween, and an approximately lateral electric field is applied to liquid crystal molecules. A thin film transistor is used for driving liquid crystal.

A manufacturing method of a thin film transistor is disclosed in JP2007-133410 A. It is possible to manufacture a thin film transistor using photolithography processing five times by the method, however, the driving voltage of the liquid crystal should be high since the insulating layer between a pair of electric fields becomes thick by forming two layers. In order to make one insulating layer, it is necessary to increase the photolithography processing. Alternatively, there has been demand for preventing the photolithography processing from increasing, regardless of the reason.

### SUMMARY OF THE INVENTION

An object of the present invention is to manufacture a liquid crystal display device without increasing photolithography processing.

(1) A liquid crystal display device according to an aspect of the present invention includes a substrate; a first transparent electrode which is formed on the substrate; a first insulating layer which is formed on the substrate so as to sit on an end portion of the first transparent electrode; a gate electrode which is arranged under the first insulating layer; a semiconductor layer which is formed on the first insulating layer; a first wiring which is formed so as to reach the first transparent electrode thereon from an upper part of the semiconductor layer, and is electrically connected to the first transparent electrode; a second wiring which is pulled out from the upper part of the semiconductor layer with an interval from the first wiring; a second insulating layer which covers the first wiring, the second wiring, the semiconductor layer, and the first transparent electrode; a second transparent electrode which is formed on the second insulating layer; and a liquid crystal layer which is arranged on the second transparent electrode, in which liquid crystal molecules of the liquid crystal layer are rotated in a plane which is parallel to the substrate by being added with an electric field in a plane direction of the substrate using a voltage which is applied between the first transparent electrode and the second transparent electrode. According to the invention, since the first wiring is electrically connected onto the first transparent electrode, it is not necessary to form a through hole in the second insulating layer. Accordingly, it is possible to manufacture a liquid crystal display device without increasing photolithography processing, in which a resistance value can be suppressed to be low due to an electrical connection not using the through hole.

(2) The liquid crystal display device which is disclosed in (1), in which an end portion of the first insulating layer may be formed so that a thickness becomes thin toward a tip end on the end portion of the first transparent electrode, and may have a slope which is inclined at an angle of inclination of an acute angle, and the first wiring may be formed on the slope.

(3) A method of manufacturing a liquid crystal display device according to another aspect of the present invention includes forming a first transparent electrode, and a gate electrode from a first transparent conductive film which is formed on a substrate, and a first metal film which is formed on the first transparent conductive film, including etching in which a first etching resist formed using a first photolithography is used; forming a first insulating layer which sits on an end portion of the first transparent electrode, and includes a semiconductor layer thereon, including etching in which a second etching resist formed using a second photolithography is used; forming a first wiring which is arranged so as to reach the first transparent electrode thereon from an upper part of the semiconductor layer, and is electrically connected to the first transparent electrode, and a second wiring which is pulled out from the upper part of the semiconductor layer with an interval from the first wiring, including etching in which a third etching resist formed using a third photolithography is used; forming a second insulating layer which covers the first wiring, the second wiring, the semiconductor layer, and the first transparent electrode, including etching in which a fourth etching resist formed using a fourth photolithography is used; forming a second transparent electrode on the second insulating layer including etching in which a fifth etching resist formed using a fifth photolithography is used; and arranging a liquid crystal layer including liquid crystal molecules rotating in a plane which is parallel to the substrate by being added with an electric field which is generated in a plane direction of the substrate using a voltage which is applied between the first transparent electrode and the second transparent electrode on the second transparent electrode. According to the invention, since it is possible to form the second insulating layer which is formed of one layer between the first transparent electrode and the second transparent electrode using the photolithography of five times, it is possible to manufacture the liquid crystal display device using photolithography processing a small number of times.

(4) The manufacturing method of the liquid crystal display device disclosed in (3), in which, in the step of forming the first transparent electrode and the gate electrode, the first etching resist may include a first thick portion and a first thin portion with thicknesses different from each other, the first thick portion may be arranged in a formation region of the gate electrode, the first thin portion may be arranged in a formation region of the first transparent electrode, the gate electrode may be formed under the first thick portion by etching the first metal film using the first thick portion and the first thin portion as masks, and the first metal film may be left in a shape corresponding to the formation region of the first transparent electrode under the first thin portion, the first thick portion may be left using a process of making the first thick portion and the first thin portion thin, the first thin portion may be removed, and the first metal film may be exposed in the formation region of the first transparent electrode, the first transparent electrode may be formed under the exposed first metal film by etching the first transparent conductive film using the exposed first metal film and the first thick portion as masks, the exposed first metal film may be removed by etching using the first thick portion as a mask, and the first etching resist may be separated.

(5) The manufacturing method of the liquid crystal display device disclosed in (4), in which, in the step of forming the first insulating layer, the semiconductor layer may be formed of a semiconductor material film, the first insulating layer may be formed from a first insulating material film, the second etching resist may include a second thick portion and a second thin portion with thicknesses different from each other, the semiconductor material film may be formed on the first insulating material film, the second thick portion may be arranged in a formation region of the semiconductor layer which is an upper part of the first insulating material film, and on the semiconductor material film, the second thin portion may be arranged in a formation region of the first insulating layer which is the upper part of the first insulating material film, and on the semiconductor material film, the first insulating layer may be formed by continuously etching the semiconductor material film and the first insulating material film using the second thick portion and the second thin portion as masks, the second thick portion may be left using a process of thinning the second thick portion and the second thin portion, the second thin portion may be removed, and the semiconductor material film may be exposed in a region other than the formation region of the semiconductor layer, the semiconductor material film may be etched using the second thick portion as a mask, and the second etching resist may be separated.

(6) The manufacturing method of the liquid crystal display device disclosed in (5), in which the first insulating material film may be etched so that a thickness of an end portion of the first, insulating layer becomes thin toward a tip end on the end portion of the first transparent electrode, and has a slope which is inclined at an angle of inclination of an acute angle.

(7) The manufacturing method of the liquid crystal display device disclosed in (5), or (6), in which, in the steps of forming the first wiring and the second wiring, the first wiring and the second wiring may be formed from a second metal film which covers the semiconductor layer, the third etching resist may be arranged in formation regions of the first wiring and the second wiring, the first wiring and the second wiring may be formed by etching the second metal film using the third etching resist as a mask, and the third etching resist may be separated.

(8) The manufacturing method of the liquid crystal display device disclosed in (7), in which the semiconductor layer may be formed so as to include a lower layer and an upper layer with larger added amount of impurities than the lower layer, and the upper layer may be etched so as to leave the lower layer of the semiconductor layer using the third etching resist as a mask after etching the second metal film.

(9) The manufacturing method of the liquid crystal display device disclosed in (7), or (8), in which, in the step of forming the second insulating layer, the second insulating layer may be formed from a second insulating material film, the fourth etching resist may be arranged in a formation region of the second insulating layer, the second insulating layer may be formed by etching the second insulating material film using the fourth etching resist as a mask, and the fourth etching resist may be separated.

(10) The manufacturing method of the liquid crystal display device disclosed in (9), in which, in the step of forming the second transparent electrode, the second transparent electrode may be formed from the second transparent conductive film, the fifth etching resist may be arranged in a formation region of the second transparent electrode, the second transparent electrode may be formed by etching the second transparent conductive film using the fifth etching resist as a mask, and the fifth etching resist may be separated.

### BRIEF DESCRIPTION OF THE DRAWINGS

FIG. 1 is a diagram which describes a manufacturing method of a liquid crystal display device according to an embodiment of the present invention.

FIG. 2 is a diagram which describes a manufacturing method of the liquid crystal display device according to the embodiment of the present invention.

FIG. 3 is a diagram which describes a manufacturing method of the liquid crystal display device according to the embodiment of the present invention.

FIG. 4 is a diagram which describes a manufacturing method of the liquid crystal display device according to the embodiment of the present invention.

FIG. 5 is a diagram which describes a manufacturing method of the liquid crystal display device according to the embodiment of the present invention.

FIG. 6 is a diagram which describes a manufacturing method of the liquid crystal display device according to the embodiment of the present invention.

FIG. 7 is a diagram which describes a manufacturing method of the liquid crystal display device according to the embodiment of the present invention.

FIG. 8 is a diagram which describes a manufacturing method of the liquid crystal display device according to the embodiment of the present invention.

FIG. 9 is a diagram which describes a manufacturing method of the liquid crystal display device according to the embodiment of the present invention.

FIG. 10 is a diagram which describes a manufacturing method of the liquid crystal display device according to the embodiment of the present invention.

FIG. 11 is a diagram which describes a manufacturing method of the liquid crystal display device according to the embodiment of the present invention.

FIG. 12 is a diagram which describes a manufacturing method of the liquid crystal display device according to the embodiment of the present invention.

FIG. 13 is a diagram which describes a manufacturing method of the liquid crystal display device according to the embodiment of the present invention.

FIG. 14 is a diagram which describes a manufacturing method of the liquid crystal display device according to the embodiment of the present invention.

FIG. 15 is a diagram which describes manufacturing method of the liquid crystal display device according to the embodiment of the present invention.

FIG. 16 is a diagram which describes a manufacturing method of the liquid crystal display device according to the embodiment of the present invention.

FIG. 17 is a diagram which describes a manufacturing method of the liquid crystal display device according to the embodiment of the present invention.

FIG. 18 is a diagram which describes a manufacturing method of the liquid crystal display device according to the embodiment of the present invention.

FIG. 19 is a diagram which describes a manufacturing method of the liquid crystal display device according to the embodiment of the present invention.

FIG. 20 is a diagram which describes a manufacturing method of the liquid crystal display device according to the embodiment of the present invention.

FIG. 21 is a diagram which describes a manufacturing method of the liquid crystal display device according to the embodiment of the present invention.

FIG. 22 is a diagram which describes a manufacturing method of the liquid crystal display device according to the embodiment of the present invention.

FIG. 23 is a diagram which describes a manufacturing method of the liquid crystal display device according to the embodiment of the present invention.

FIG. 24 is a diagram which describes a manufacturing method of the liquid crystal display device according to the embodiment of the present invention.

FIG. 25 is a diagram which describes a manufacturing method of the liquid crystal display device according to the embodiment of the present invention.

FIG. 26 is a diagram which describes a manufacturing method of the liquid crystal display device according to the embodiment of the present invention.

### DETAILED DESCRIPTION OF THE INVENTION

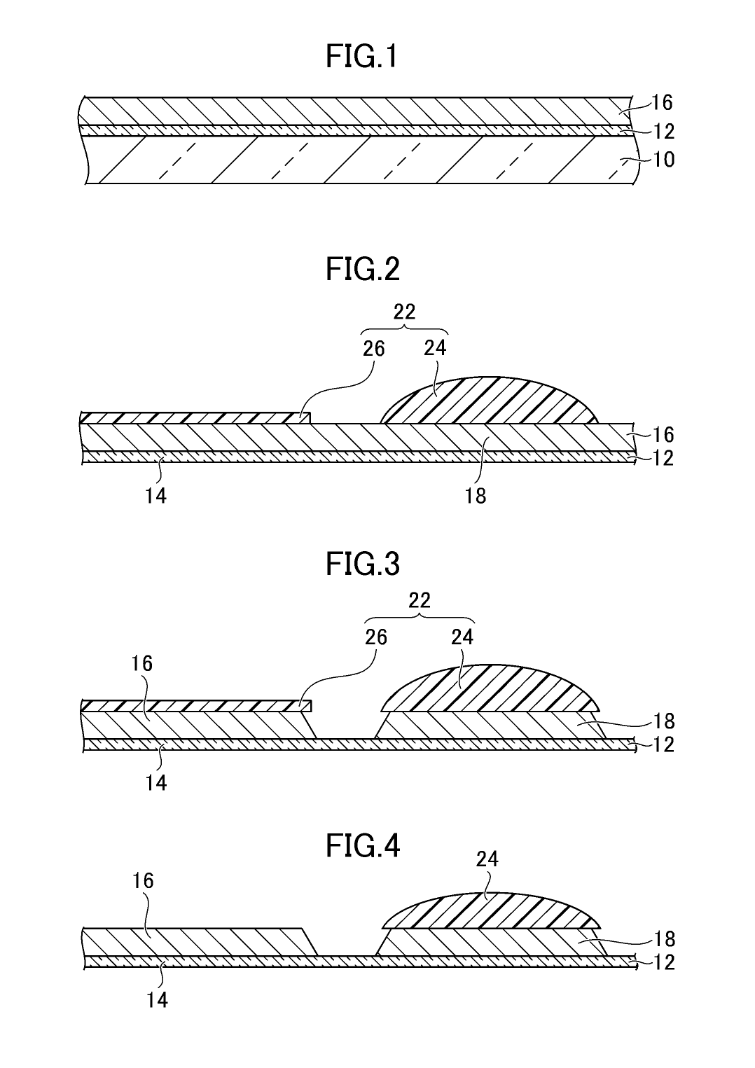

Hereinafter, the embodiment of the present invention will be described with reference to drawings. FIGS. 1 to 26 are diagrams which describe a manufacturing method of the liquid crystal display device according to the embodiment of the present invention.

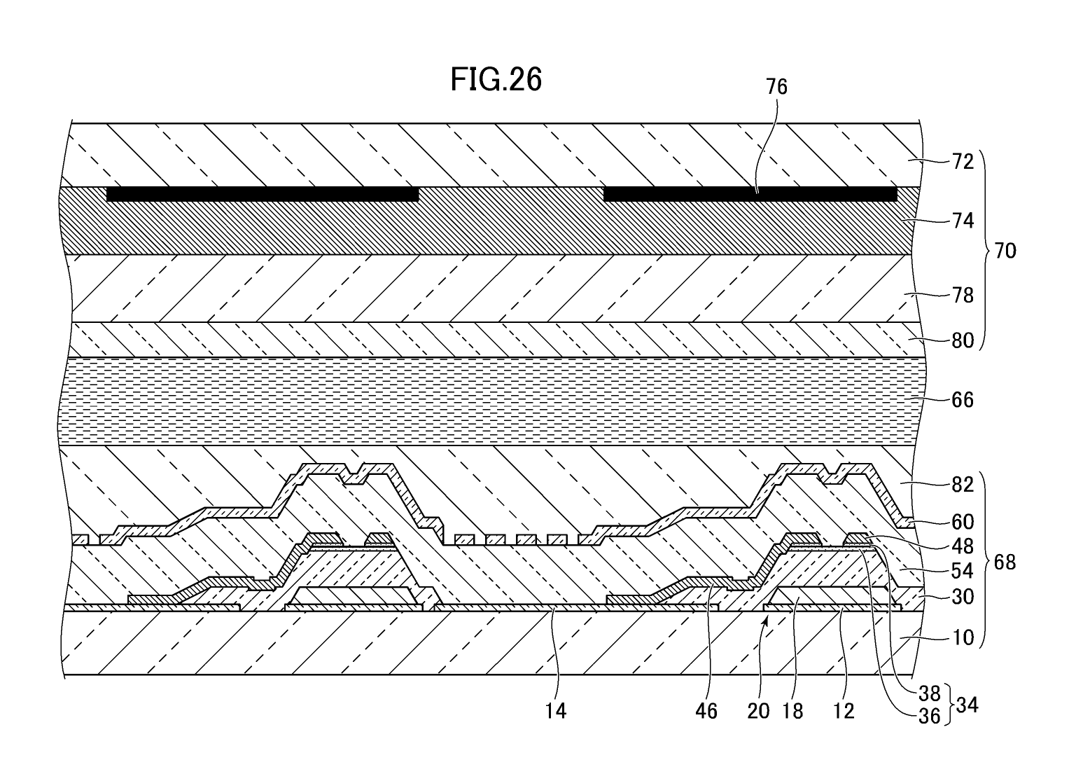

As illustrated in FIG. 1, a first transparent conductive film 12 is formed on a substrate 10. In addition, in FIGS. 2 to 25, the substrate 10 will be omitted in the drawings. The substrate 10 is formed of a material with optical transparency such as glass. The first transparent conductive film 12 is formed of, for example, ITO (Indium Tin Oxide). According to the embodiment, a lateral electric field liquid crystal display device in which liquid crystal molecules are rotated in a plane which is parallel to the substrate 10 by being added with an electric field in the plane direction of the substrate 10, or an IPS (In Plane Switching) liquid crystal display device is manufactured. The first transparent conductive film 12 is a film which forms a first transparent electrode 14, as described later (refer to FIG. 26). The first transparent electrode 14 is an electrode on one side which generates an electric field. According to the embodiment, the first transparent electrode 14 is a pixel electrode which is provided in each pixel.

In addition, a first metal film 16 is formed on the first transparent conductive film 12. The first metal film 16 is formed of, for example, aluminum. The first metal film 16 is a film which forms a gate electrode 18, as described later (refer to FIG. 26). The gate electrode 18 is a constituent element of a thin film transistor 20.

As illustrated in FIG. 2, a first etching resist 22 is formed using a first photolithography. Photolithography is a technology in which a pattern which is formed by an exposed portion and an unexposed portion is generated by causing the surface of a material onto which a photosensitive material is applied to be exposed to light in a shape of a pattern (also called as pattern exposure or image-wise exposure).

The first etching resist 22 is formed so as to include a first thick portion 24 and a first thin portion 26 with thicknesses different from each other. For this reason, the first photolithography includes halftone exposure. The first thick portion 24 is arranged in a formation region of the gate electrode 18. The first thin portion 26 is arranged in a formation region of the first transparent electrode 14.

As illustrated in FIG. 3, the first metal film 16 is etched using the first thick portion 24 and the first thin portion 26 as masks. The etching is wet etching, however, a liquid solution which does not etch the first transparent conductive film 12 is used. Due to the etching, the gate electrode 18 is formed under the first thick portion 24, and the first metal film 16 is left in a shape corresponding to the formation region of the first transparent electrode 14 under the first thin portion 26.

As illustrated in FIG. 4, processing for making the first thick portion 24 and the first thin portion 26 thin is performed. This processing is asking. In this manner, the first thin portion 26 is removed, and the first metal film 16 is exposed in the formation region of the first transparent electrode 14. However, the first thick portion 24 is left.

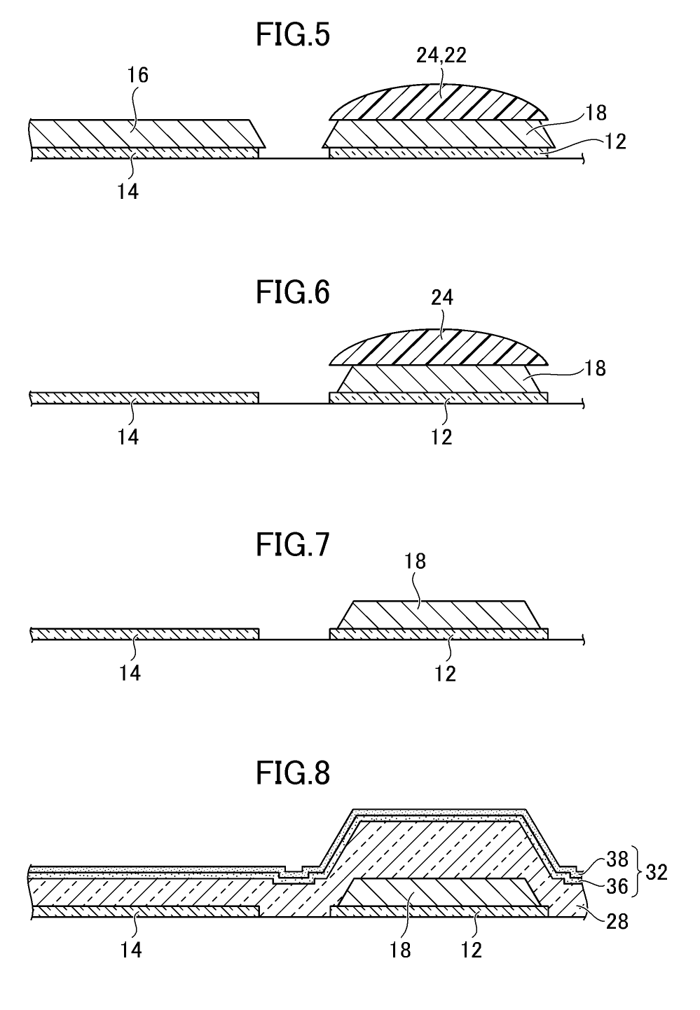

As illustrated in FIG. 5, the first transparent conductive film 12 is etched using the first metal film 16 which is exposed from the first etching resist 22, and the first thick portion 24 as masks. This etching is wet etching, however, a liquid solution which does not etch the first metal film 16 is used. Due to this etching, the first transparent electrode 14 is formed under the first metal film 16 which is exposed from the first etching resist 22.

As illustrated in FIG. 6, the exposed first metal film 16 is etched and removed using the first thick portion 24 as a mask. This etching is the wet etching, however, a liquid solution which does not etch the first transparent conductive film 12 is used.

As illustrated in FIG. 7, the first etching resist 22 is separated. A liquid solution is used for the separation. When the first etching resist 22 is removed, the gate electrode 18 is exposed.

As illustrated in FIG. 8, a first insulating material film 28 is formed on the substrate 10 (Refer to FIG. 1. It is omitted in FIG. 8.). The first insulating material film 28 is formed of SiN using, for example, plasma CVD (Plasma-Enhanced Chemical Vapor Deposition). The first insulating material film 28 is a film for forming a first insulating layer 30 to be described later (refer to FIG. 26). The first insulating material film 28 is formed so as to cover the first transparent electrode 14, and the gate electrode 18.

A semiconductor material film 32, for example, such as amorphous silicon is formed on the first insulating material film 28. The semiconductor material film 32 is a film for forming a semiconductor layer 34 as a constituent element of the thin film transistor 20, as described below (refer to FIG. 26). The semiconductor layer 34 is formed so as to include a lower layer 36, and an upper layer 38 with larger added amount of impurities than the lower layer 36.

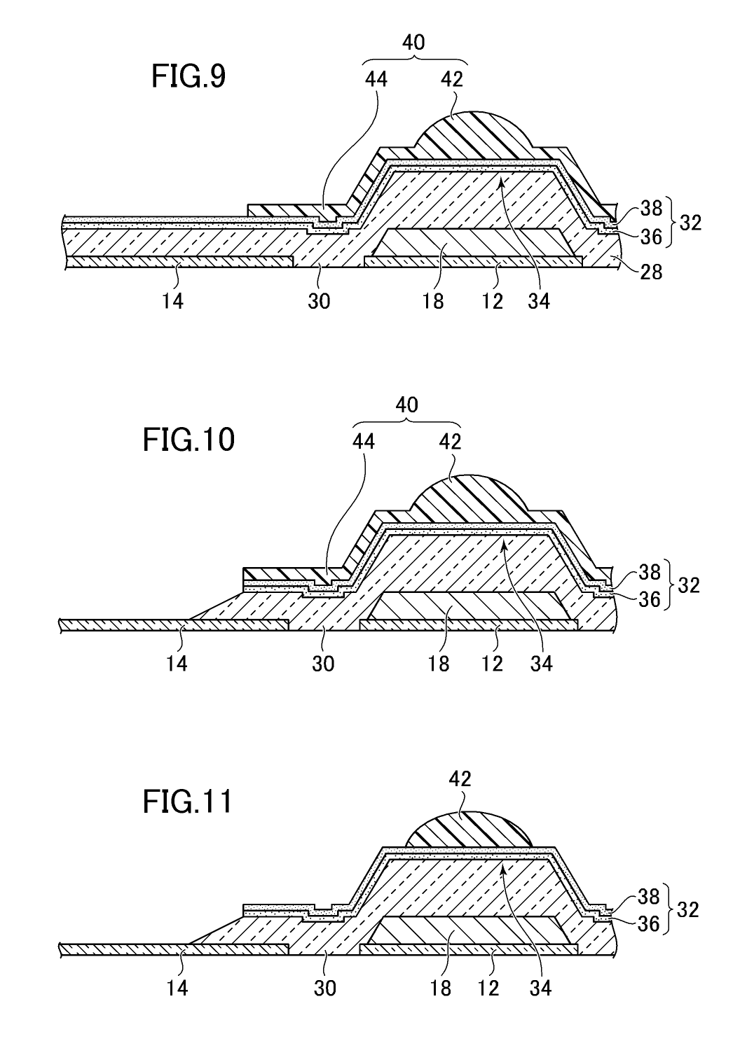

As illustrated in FIG. 9, a second etching resist 40 is formed using a second photolithography. The second etching resist 40 is formed so as to include a second thick portion 42 and a second thin portion 44 with thicknesses different from each other. For this reason, the second photolithography includes the halftone exposure. The second thick portion 42 is arranged in a formation region of the semiconductor layer 34 which is the upper part of the first insulating material film 28, and on the semiconductor material film 32. The second thin portion 44 is arranged in a formation region of the first insulating layer 30 which is the upper part of the first insulating material layer 28, and on the semiconductor material film 32.

As illustrated in FIG. 10, the first insulating layer 30 is formed by continuously etching the semiconductor material film 32 and the first insulating material film 28 using the second thick portion 42 and the second thin portion 44 as masks. This etching is dry etching. The first insulating layer 30 is formed so as to sit on an end portion of the first transparent electrode 14. In addition, the first insulating material film 28 is etched so that the thickness of an end portion of the first insulating layer 30 becomes thin toward a tip end on the end portion of the first transparent electrode 14, and has a slope which is inclined at an angle of inclination of an acute angle (for example, approximately 10°). Etching conditions are adjusted so that the end portion of the first insulating layer 28 has such a shape.

As illustrated in FIG. 11, processing of making the second thick portion 42 and the second thin portion 44 thin is performed. This processing is the ashing. In this manner, the second thin portion 44 is removed. In addition, the semiconductor material film 32 is exposed from the second etching resist 40 in other regions than the formation region of the semiconductor layer 34. In addition, the second thick portion 42 is left.

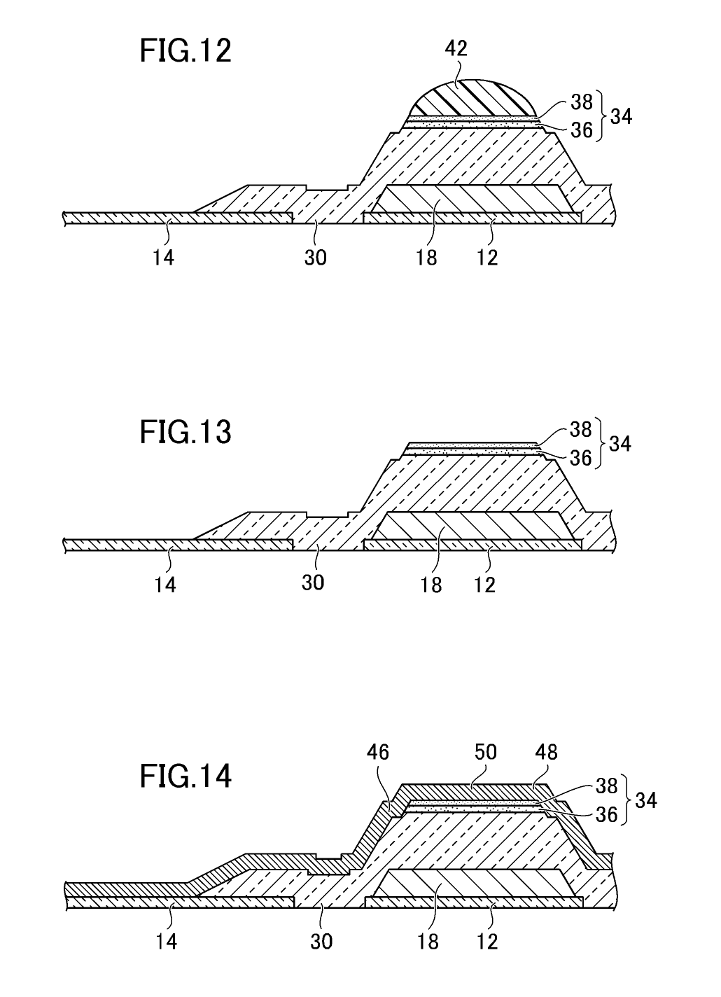

As illustrated in FIG. 12, the semiconductor layer 34 is formed by etching the semiconductor material film 32 using the second thick portion 42 as a mask.

As illustrated in FIG. 13, the second etching resist 40 is separated. The liquid solution is used for the separation. When the second etching resist 40 is removed, the semiconductor layer 34 is exposed.

As illustrated in FIG. 14, a second metal film 50 for forming a first wiring 46 and a second wiring 48 is formed so as to cover the semiconductor layer 34. The first wiring 46 and the second wiring 48 are drain wiring and source wiring of the thin film transistor 20 (refer to FIG. 26).

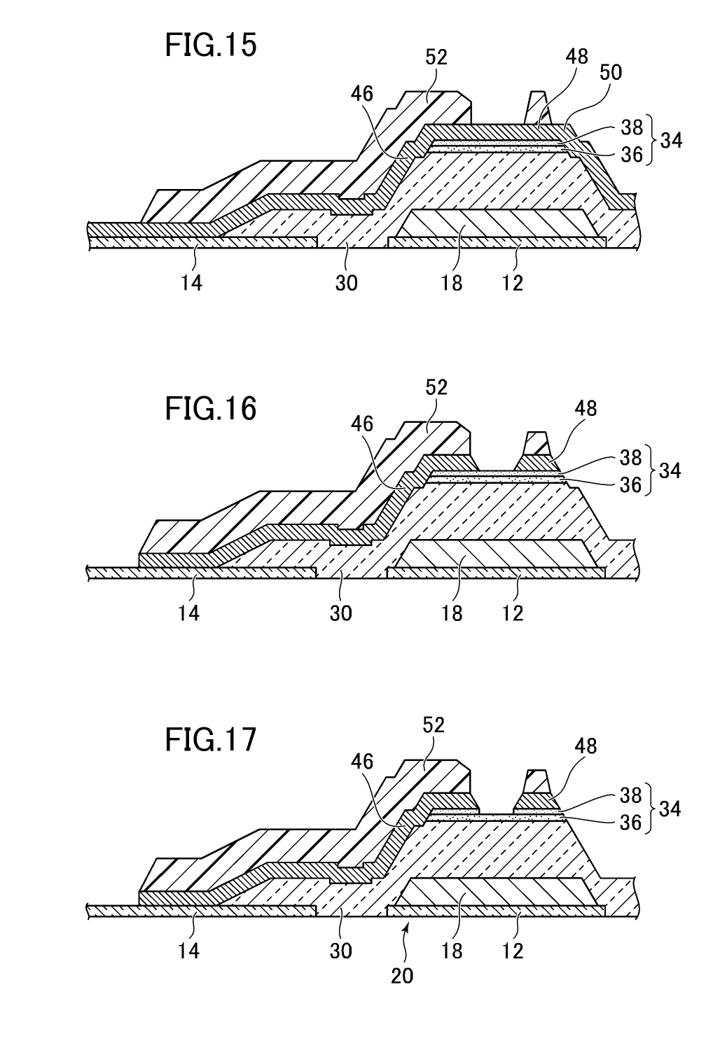

As illustrated in FIG. 15, a third etching resist 52 is formed using a third photolithography. The third etching resist 52 is arranged in a formation region of the first wiring 46 and the second wiring 48.

As illustrated in FIG. 16, the first wiring 46 and the second wiring 48 are formed by etching the second metal film 50 using the third etching resist 52 as a mask. This etching is the wet etching. The first wiring 46 is formed so as to reach the first transparent electrode 14 thereon from the top of the semiconductor layer 34, and is electrically connected to the first transparent electrode 14. The second wiring 48 is pulled out from the upper part of the semiconductor layer 34 with an interval from the first wiring 46.

As illustrated in FIG. 17, the upper layer 38 is etched so as to leave the lower layer 36 of the semiconductor layer 34 using the third etching resist 52 as a mask after etching the second metal film 50. That is, the upper layer 38 with large added amount of impurities is divided into the drain region and the source region.

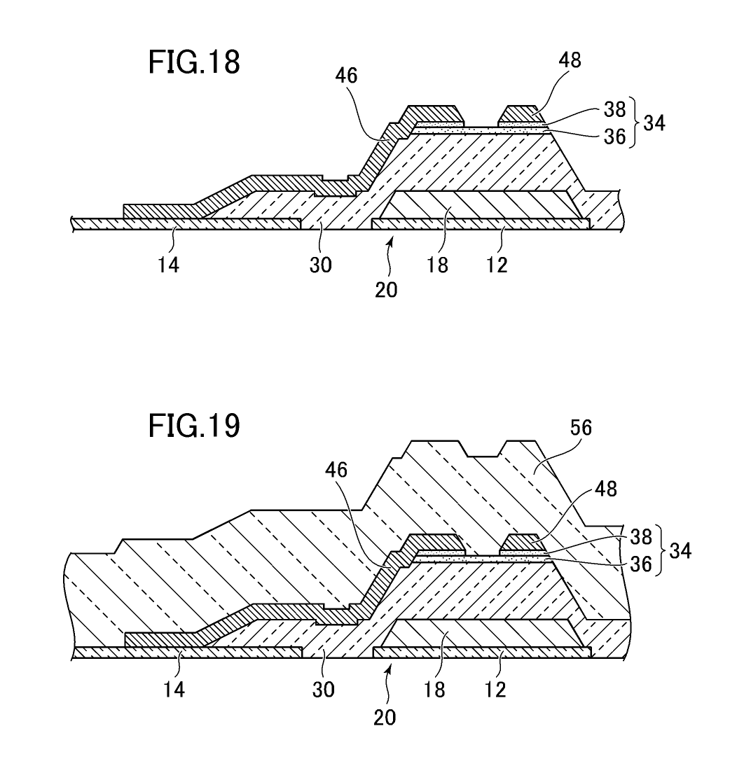

As illustrated in FIG. 18, the third etching resist 52 is separated. The liquid solution is used for the separation. When the third etching resist 52 is separated, the first wiring 46 and the second wiring 48 are exposed.

As illustrated in FIG. 19, a second insulation material film 56 for forming a second insulating layer 54 is formed so as to cover the first wiring 46, the second wiring 48, the semiconductor layer 34 and the first transparent electrode 14. The second insulating material film 56 is formed of SiN using, for example, plasma CVD (Plasma-Enhanced Chemical Vapor Deposition).

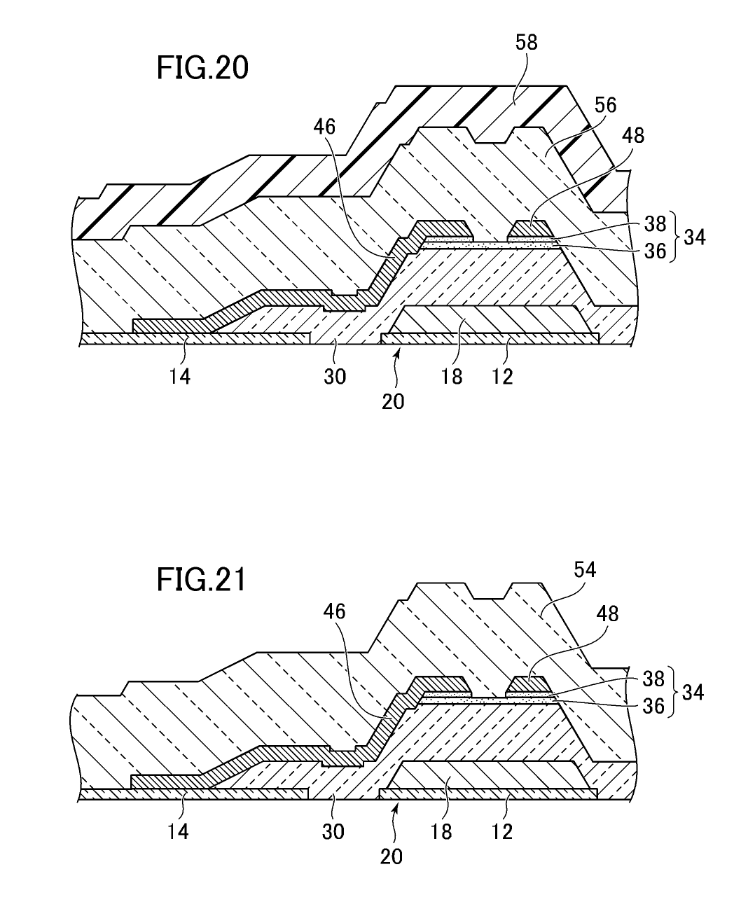

As illustrated in FIG. 20, a fourth etching resist 58 is formed using a fourth photolithography. The fourth etching resist 58 is arranged in a formation region of the second insulating layer 54 (refer to FIG. 21). The second insulating layer 54 is formed with a though hole, or a notch, which is not shown, for electrical connection to various wirings thereunder, the fourth etching resist 58 is formed so as to expose a formation region of the through hole, or the notch. In addition, the second insulating layer 54 (refer to FIG. 21) is formed by etching the second insulating layer 56 using the fourth etching resist 58 as a mask. This etching is the dry etching.

As shown in FIG. 21, the fourth etching resist 58 is separated. The liquid solution is used for the separation. When the fourth etching resist 58 is removed, the second insulating layer 54 is exposed.

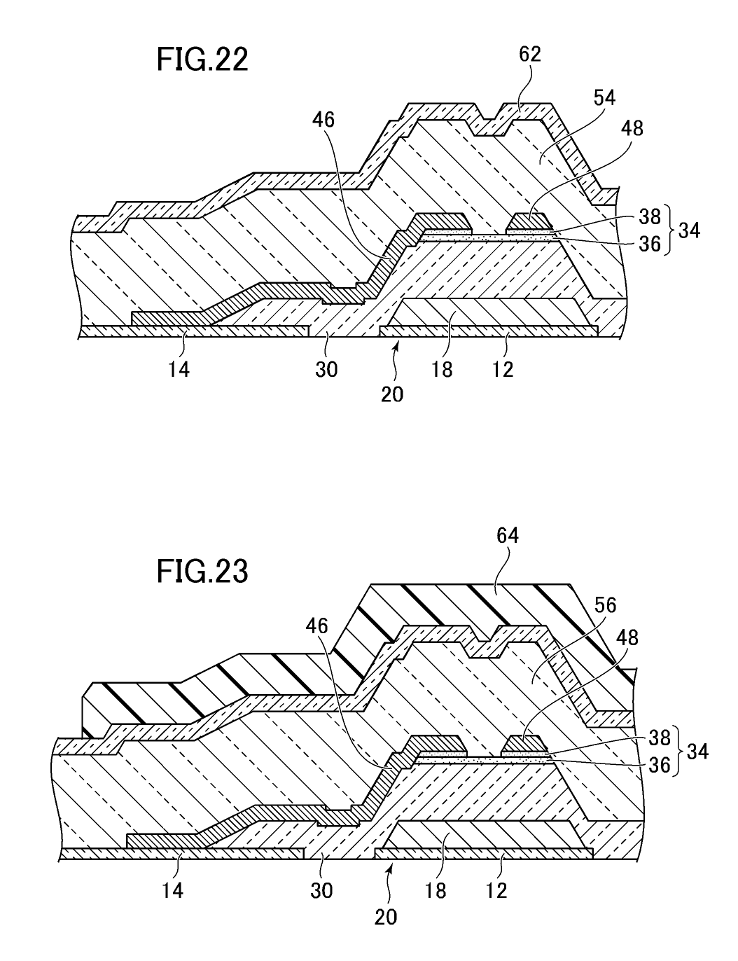

As illustrated in FIG. 22, a second transparent conductive film 62 for forming a second transparent electrode 60 is formed on the second insulating layer 54. The second transparent conductive film 62 is formed of, for example, ITO (Indium Tin Oxide). The second transparent electrode 60 is an electrode on the other side which generates an electric field in the method of lateral electric field, or the IPS (In Plane Switching). According to the embodiment, the second transparent electrode 60 is a common electrode facing all of the pixel electrodes (refer to FIG. 26).

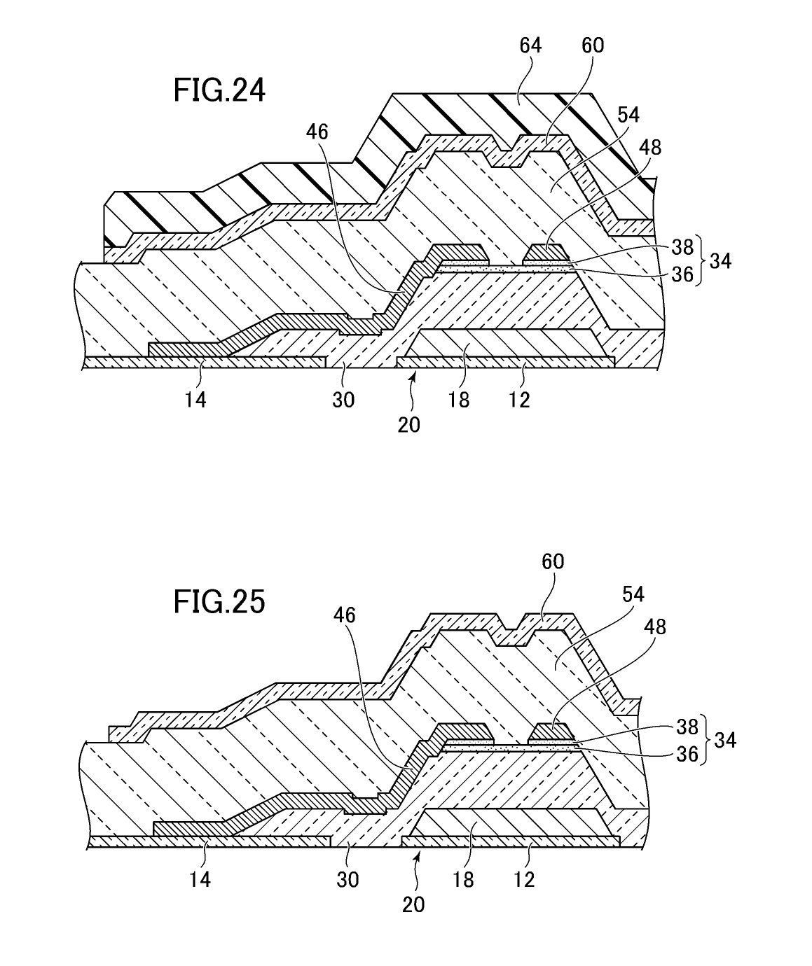

As illustrated in FIG. 23, a fifth etching resist 64 is formed using a fifth photolithography. The fifth etching resist 64 is arranged in a formation region of the second transparent electrode 60 (refer to FIG. 24).

As illustrated in FIG. 24, the second transparent electrode 60 is formed by etching the second transparent conductive film 62 using the fifth etching resist 64 as a mask.

As illustrated in FIG. 25, the fifth etching resist 64 is separated. The liquid solution is used for the separation. When the fifth etching resist 64 is removed, the second transparent electrode 60 is exposed.

As illustrated in FIG. 26, a liquid crystal layer 66 is arranged on the second transparent electrode 60. Specifically, in the above described processing, a TFT substrate 68 in which a circuit including the thin film transistor 20 is formed is obtained, and the liquid crystal layer 66 is interposed between the TFT substrate 68 and a color filter substrate 70 which is prepared separately from the TFT substrate.

The color filter substrate 70 includes a substrate 72, a color filter 74, a black matrix 76, a planarizing layer 78, and an alignment film 80. In addition, an alignment film 82 is formed on the TFT substrate 68 so as to cover the second transparent electrode 60. The liquid crystal layer 66 is interposed between the color filter substrate 70 and the oriented films 80 and 82 of the TFT substrate 68. The liquid crystal molecules of the liquid crystal layer 66 rotate in the plane which is parallel to the substrate 10 by being added with the electric field which is generated in the plane direction of the substrate 10 using a voltage which is applied between the first transparent electrode 14 and the second transparent electrode 60.

According to the embodiment, since it is possible to form the second insulating layer 54 of one layer between the first transparent electrode 14 and the second transparent electrode 60 using the photolithography of five times, the liquid crystal display device can be manufactured using a small number of photolithography processes.

The liquid crystal display device which is illustrated in FIG. 26 includes the substrate 10. The first transparent electrode 14 is formed on the substrate 10. The first insulating layer 30 is formed on the substrate 10 so as to sit on the end portion of the first transparent electrode 14. The end portion of the first insulating layer 30 is formed so that the thickness thereof becomes thin toward the tip end on the end portion of the first transparent electrode 14. For this reason, the first insulating layer 30 has a slope which is inclined at an angle of inclination of an acute angle (for example, approximately 10°).

The gate electrode 18 is arranged under the first insulating layer 30. The semiconductor layer 34 is formed on the first insulating layer 30. The first wiring 46 is formed so as to reach the first transparent electrode 14 thereon from the top of the semiconductor layer 34., The first wiring 46 which is electrically connected to the first transparent electrode 14 is formed on the slope of the first insulating layer 30.

The second wiring 48 is pulled out from the top of the semiconductor layer 34 with an interval from the first wiring 46. The second insulating layer 54 is formed so as to cover the first wiring 46, the second wiring 48, the semiconductor layer 34, and the first transparent electrode 14. The second transparent electrode 60 is formed on the second insulating layer 54.

The liquid crystal layer 66 is arranged on the second transparent electrode 60. The liquid crystal molecules of the liquid crystal layer 66 are rotated in the plane which is parallel to the substrate 10 by adding the electric field in the plane direction of the substrate 10 using a voltage which is applied between the first transparent electrode 14 and the second transparent electrode 60.

According to the embodiment, since the first wiring 46 is electrically connected onto the first transparent electrode 14, it is not necessary to form a through hole in the second insulating layer 54. Accordingly, it is possible to manufacture a liquid crystal display device in which the resistance value is suppressed to be low using an electrical connection in which the through hole is not used, without increasing the photolithography processing.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A liquid crystal display device comprising:
a substrate;
a first transparent electrode which is formed on the substrate;
a first insulating layer which is formed on the substrate so as to sit on an end portion of the first transparent electrode;
a gate electrode which is arranged under the first insulating layer;
a semiconductor layer which is formed on the first insulating layer;
a first wiring which is formed so as to reach the first transparent electrode thereon from an upper part of the semiconductor layer, and is electrically connected to the first transparent electrode;
a second wiring which is pulled out from the upper part of the semiconductor layer with an interval from the first wiring;
a second insulating layer which covers the first wiring, the second wiring, the semiconductor layer, and the first transparent electrode;
a second transparent electrode which is formed on the second insulating layer; and
a liquid crystal layer which is arranged on the second transparent electrode,
wherein liquid crystal molecules of the liquid crystal layer are rotated in a plane which is parallel to the substrate by being added with an electric field in a plane direction of the substrate using a voltage which is applied between the first transparent electrode and the second transparent electrode.

2. The liquid crystal display device according to claim 1,
wherein an end portion of the first insulating layer is formed so that a thickness becomes thin toward a tip end on the end portion of the first transparent electrode, and has a slope which is inclined at an angle of inclination of an acute angle, and
wherein the first wiring is formed on the slope.

3. A method of manufacturing a liquid crystal display device comprising steps of:
forming a first transparent electrode, and a gate electrode from a first transparent conductive film which is formed on a substrate, and a first metal film which is formed on the first transparent conductive film, including etching in which a first etching resist formed using a first photolithography is used;
forming a first insulating layer which sits on an end portion of the first transparent electrode, and includes a semiconductor layer thereon, including etching in which a second etching resist formed using a second photolithography is used;
forming a first wiring which is arranged so as to reach the first transparent electrode thereon from an upper part of the semiconductor layer, and is electrically connected to the first transparent electrode, and a second wiring which is pulled out from the upper part of the semiconductor layer with an interval from the first wiring, including etching in which a third etching resist formed using a third photolithography is used;
forming a second insulating layer which covers the first wiring, the second wiring, the semiconductor layer, and the first transparent electrode, including etching in which a fourth etching resist formed using a fourth photolithography is used;
forming a second transparent electrode on the second insulating layer including etching in which a fifth etching resist formed using a fifth photolithography is used; and
arranging a liquid crystal layer including liquid crystal molecules rotating in a plane which is parallel to the substrate by being added with an electric field which is generated in a plane direction of the substrate using a voltage which is applied between the first transparent electrode and the second transparent electrode on the second transparent electrode.

4. The manufacturing method of the liquid crystal display device according to claim 3,
wherein, in the step of forming the first transparent electrode and the gate electrode,
the first etching resist includes a first thick portion and a first thin portion with thicknesses different from each other,
the first thick portion is arranged in a formation region of the gate electrode,
the first thin portion is arranged in a formation region of the first transparent electrode,
the gate electrode is formed under the first thick portion by etching the first metal film using the first thick portion and the first thin portion as masks, and the first metal film is left in a shape corresponding to the formation region of the first transparent electrode under the first thin portion,
the first thick portion is left using a process of making the first thick portion and the first thin portion thin, the first thin portion is removed, and the first metal film is exposed in the formation region of the first transparent electrode,
the first transparent electrode is formed under the exposed first metal film by etching the first transparent conductive film using the exposed first metal film and the first thick portion as masks,
the exposed first metal film is removed by etching using the first thick portion as a mask, and
the first etching resist is separated.

5. The manufacturing method of the liquid crystal display device according to claim 4,
wherein, in the step of forming the first insulating layer,
the semiconductor layer is formed of a semiconductor material film,
the first insulating layer is formed from a first insulating material film,
the second etching resist includes a second thick portion and a second thin portion with thicknesses different from each other,
the semiconductor material film is formed on the first insulating material film,
the second thick portion is arranged in a formation region of the semiconductor layer which is an upper part of the first insulating material film, and on the semiconductor material film,
the second thin portion is arranged in a formation region of the first insulating layer which is the upper part of the first insulating material film, and on the semiconductor material film,
the first insulating layer is formed by continuously etching the semiconductor material film and the first insulating material film using the second thick portion and the second thin portion as masks,
the second thick portion is left using a process of thinning the second thick portion and the second thin portion, the second thin portion is removed, and the semiconductor material film is exposed in a region other than the formation region of the semiconductor layer,
the semiconductor material film is etched using the second thick portion as a mask, and
the second etching resist is separated.

6. The manufacturing method of the liquid crystal display device according to claim 5,
wherein the first insulating material film is etched so that a thickness of an end portion of the first insulating layer becomes thin toward a tip end on the end portion of the first transparent electrode, and has a slope which is inclined at an angle of inclination of an acute angle.

7. The manufacturing method of the liquid crystal display device according to claim 5,
wherein in the steps of forming the first wiring and the second wiring,
the first wiring and the second wiring are formed from a second metal film which covers the semiconductor layer,
the third etching resist is arranged in formation regions of the first wiring and the second wiring,
the first wiring and the second wiring are formed by etching the second metal film using the third etching resist as a mask, and
the third etching resist is separated.

8. The manufacturing method of the liquid crystal display device according to claim 7,
wherein the semiconductor layer is formed so as to include a lower layer and an upper layer with larger added amount of impurities than the lower layer, and
wherein the upper layer is etched so as to leave the lower layer of the semiconductor layer using the third etching resist as a mask after etching the second metal film.

9. The manufacturing method of the liquid crystal display device according to claim 7,
wherein in the step of forming the second insulating layer,
the second insulating layer is formed from a second insulating material film,
the fourth etching resist is arranged in a formation region of the second insulating layer,
the second insulating layer is formed by etching the second insulating material film using the fourth etching resist as a mask, and
the fourth etching resist is separated.

10. The manufacturing method of the liquid crystal display device according to claim 9,
wherein in the step of forming the second transparent electrode,
the second transparent electrode is formed from the second transparent conductive film,
the fifth etching resist is arranged in a formation region of the second transparent electrode,
the second transparent electrode is formed by etching the second transparent conductive film using the fifth etching resist as a mask, and
the fifth etching resist is separated.
